(19) United States
(12) Patent Application Publication
(10) Pub. No.: US 2026/0040599 A1
(43) Pub. Date: Feb. 5, 2026

(54) GATE ALL-AROUND FIELD EFFECT TRANSISTOR AND METHOD FOR FABRICATING THE SAME

(71) Applicants: Materials Analysis Technology Inc., Hsinchu County (TW); NATIONAL TAIWAN UNIVERSITY, TAIPEI CITY (TW)

(72) Inventors: Yuan-Ming Liu, Taichung City (TW); Jih-Chao Chiu, New Taipei City (TW); Yu-Shan Wu, New Taipei City (TW); Chee-Wee Liu, Taipei City (TW); HUNG-JEN CHEN, Hsinchu City (TW)

(21) Appl. No.: 19/267,660

(22) Filed: Jul. 14, 2025

Related U.S. Application Data
(60) Provisional application No. 63/678,523, filed on Aug. 1, 2024.

(51) Int. Cl. H10D 30/01; H10D 30/67

(52) U.S. Cl. CPC H10D 30/031; H10D 30/6704; H10D 30/6735; H10D 30/6756

(57) ABSTRACT

A gate all-around field effect transistor includes a substrate, a first sacrificial layer, a channel layer, a protective layer, a composite field oxide layer, a drain electrode, a source electrode and a gate stack layer. The first sacrificial layer is disposed on the substrate. The channel layer is disposed on the first sacrificial layer, and extends from a drain region to a source region. The protective layer is disposed on the channel layer in the drain and source regions. The composite field oxide layer is disposed on the protective layer in the drain and source regions, and has a drain opening and a source opening for exposing the protective layer. The drain and source electrodes are respectively disposed in the drain and source openings, and in electrical contact with the protective layer. The gate stack layer is disposed on the substrate in the channel region.

### CROSS-REFERENCE TO RELATED PATENT APPLICATION

This application claims the benefit of priority to the U.S. Provisional Patent Application Ser. No. 63/678,523, filed on Aug. 1, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device and a method, and more particularly to a gate all-around field effect transistor (GAAFET) and a method for fabricating the same.

### BACKGROUND OF THE DISCLOSURE

Amorphous indium gallium zinc oxide (a-IGZO) has attracted widespread attention in recent years, primarily due to its low processing temperature, moderate mobility, and high uniformity. The a-IGZO has highly uniform amorphous characteristics, making it highly promising for applications in Monolithic 3D (M3D) integration.

The a-IGZO has a higher bandgap, which gives it an extremely low off-current, but its mobility limits improvement of an on-current. Therefore, in a conventional a-IGZO gate-around (GAA) structure, an on-current is increased and a gate control capability is improved for reducing subthreshold swing (SS) and an off current.

However, in the conventional a-IGZO GAA structure, material properties of channel layers are easily affected during processing, resulting in poor electrical characteristics. Additionally, electrode opening dimensions are limited by the processes, causing a final circuit component to exhibit a relatively high series resistance, which in turn adversely affects performance of the final circuit component. Therefore, overcoming the above-mentioned problems through improvements in processes and structures has become an important issue to be addressed in the relevant field.

### SUMMARY OF THE DISCLOSURE

In response to the above-referenced technical inadequacies, the present disclosure provides a gate all-around field effect transistor and a method for fabricating the same.

In order to solve the above-mentioned problems, one of the technical aspects adopted by the present disclosure is to provide the method for fabricating the gate all-around field effect transistor. The method includes: sequentially forming a first sacrificial layer, a channel layer and a protective layer on a substrate; performing a first patterning process on the first sacrificial layer, the channel layer and the protective layer to form a fin structure; forming a composite field oxide layer to cover the fin structure and the substrate and to surround the fin structure; performing a second patterning process on the composite field oxide layer to remove one portion of the composite field oxide layer in a channel region, and to retain another portion of the composite field oxide layer in a drain region and a source region on two sides of the channel region; removing the protective layer, the first sacrificial layer and the one portion of the composite field oxide layer in the channel region to release the channel layer; forming a gate stack layer on the another portion of the composite field oxide layer in the drain region and the source region, the substrate in the channel region and a surface of the channel layer; performing a third patterning process on the gate stack layer to remove the gate stack layer from the drain region and the source region; performing a fourth patterning process on the composite field oxide layer to form a drain opening in the drain region and a source opening in the source region; and forming a drain electrode in the drain opening and a source electrode in the source opening and electrically connecting the drain electrode and the source electrode to the protective layer.

In order to solve the above-mentioned problems, one of the technical aspects adopted by the present disclosure is to provide the gate all-around field effect transistor. The gate all-around field effect transistor includes a substrate, a first sacrificial layer, a channel layer, a protective layer, a composite field oxide layer, a drain electrode, a source electrode, and a gate stack layer. The substrate defines a channel region, and defines a drain region and a source region on two sides of the channel region. The first sacrificial layer is disposed on the substrate in the drain region and the source region. The channel layer is disposed on the first sacrificial layer and extends from the drain region to the source region. The protective layer is disposed on the channel layer in the drain region and the source region. The composite field oxide layer is disposed on the protective layer in the drain region and the source region. The composite field oxide layer has a drain opening in the drain region and a source opening in the source region. The drain opening and the source opening expose the protective layer. The drain electrode and a source electrode are in electrical contact with the protective layer. The drain electrode is disposed in the drain opening, and the source electrode is disposed in the source opening. The gate stack layer is disposed on the substrate in the channel region and disposed to surround the channel layer.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart diagram of a method for fabricating a gate all-around field effect transistor according to a first embodiment of the present disclosure;

FIG. 2 is a top view of the gate all-around field effect transistor in process S10 according to the first embodiment of the present disclosure;

FIG. 3 is a cross-sectional view of the gate all-around field effect transistor in process S10 according to the first embodiment of the present disclosure;

FIG. 4 is a detailed flowchart diagram of process S11;

FIG. 5 is a top view of the gate all-around field effect transistor in procedure S110 according to the first embodiment of the present disclosure;

FIG. 6 is a cross-sectional view of the gate all-around field effect transistor in procedure S110 according to the first embodiment of the present disclosure;

FIG. 7 is a top view of the gate all-around field effect transistor in procedure S111 according to the first embodiment of the present disclosure;

FIG. 8 is a cross-sectional view of the gate all-around field effect transistor in procedure S111 according to the first embodiment of the present disclosure;

FIG. 9 is a top view of the gate all-around field effect transistor in process S12 according to the first embodiment of the present disclosure;

FIG. 10 is a cross-sectional view of the gate all-around field effect transistor in process S12 according to the first embodiment of the present disclosure;

FIG. 11 is a detailed flowchart diagram of process S13;

FIG. 12 is a top view of the gate all-around field effect transistor in procedure S130 according to the first embodiment of the present disclosure;

FIG. 13 is a cross-sectional view of the gate all-around field effect transistor in procedure S130 according to the first embodiment of the present disclosure;

FIG. 14 is a top view of the gate all-around field effect transistor in procedure S131 according to the first embodiment of the present disclosure;

FIG. 15 is a cross-sectional view of the gate all-around field effect transistor in procedure S131 according to the first embodiment of the present disclosure;

FIG. 16 is a top view of the gate all-around field effect transistor in process S14 according to the first embodiment of the present disclosure;

FIG. 17 is a cross-sectional view of the gate all-around field effect transistor in process S14 according to the first embodiment of the present disclosure;

FIG. 18 is a top view of the gate all-around field effect transistor in process S16 according to the first embodiment of the present disclosure;

FIG. 19 is a cross-sectional view of the gate all-around field effect transistor in process S16 according to the first embodiment of the present disclosure;

FIG. 20 is a detailed flowchart diagram of process S17;

FIG. 21 is a top view of the gate all-around field effect transistor in procedure S170 according to the first embodiment of the present disclosure;

FIG. 22 is a cross-sectional view of the gate all-around field effect transistor in procedure S170 according to the first embodiment of the present disclosure;

FIG. 23 is a top view of the gate all-around field effect transistor in process S172 according to the first embodiment of the present disclosure;

FIG. 24 is a cross-sectional view of the gate all-around field effect transistor in process S172 according to the first embodiment of the present disclosure;

FIG. 25 is a detailed flowchart diagram of process S18;

FIG. 26 is a top view of the gate all-around field effect transistor in procedure S180 according to the first embodiment of the present disclosure;

FIG. 27 is a cross-sectional view of the gate all-around field effect transistor in procedure S180 according to the first embodiment of the present disclosure;

FIG. 28 is a top view of the gate all-around field effect transistor in procedure S181 according to the first embodiment of the present disclosure;

FIG. 29 is a cross-sectional view of the gate all-around field effect transistor in procedure S181 according to the first embodiment of the present disclosure;

FIG. 30 is a top view of the gate all-around field effect transistor in process S19 according to the first embodiment of the present disclosure;

FIG. 31 is a cross-sectional view of the gate all-around field effect transistor in process S19 according to the first embodiment of the present disclosure;

FIG. 32 is a top view of a gate all-around field effect transistor according to a second embodiment of the present disclosure;

FIG. 33 is a cross-sectional view of the gate all-around field effect transistor according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The main purpose of the present disclosure is to provide a gate all-around field effect transistor and a method for fabricating the same. The gate all-around field effect transistor of the present disclosure exhibits a small series resistance, large on-current and high carrier mobility, and can be manufactured with higher yield, by overcoming limitations of conventional fabrication processes.

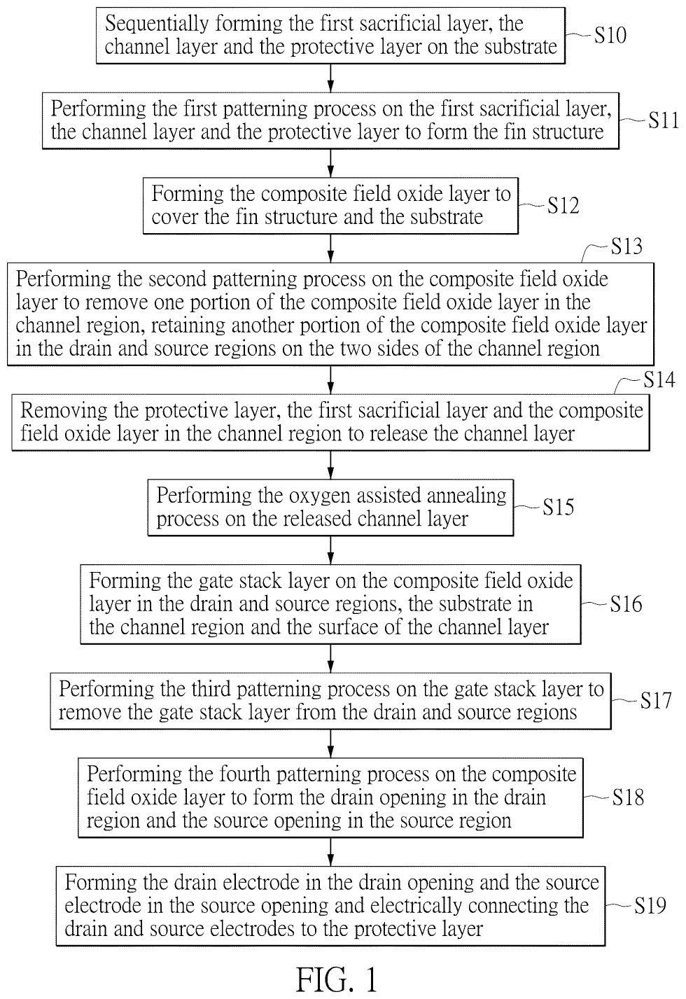

Reference is made to FIG. 1, which is a flowchart diagram of a method for fabricating a gate all-around field effect transistor according to a first embodiment of the present disclosure. In the first embodiment, the present disclosure provides the method for fabricating the gate all-around field effect transistor, which includes processes S11 to S19.

In process S10, a first sacrificial layer, a channel layer and a protective layer are sequentially formed on a substrate.

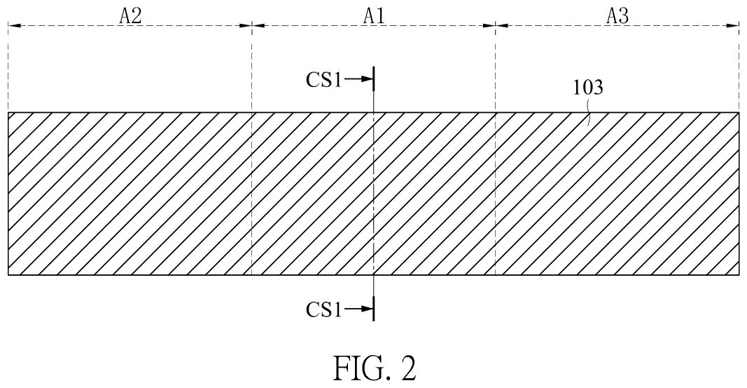

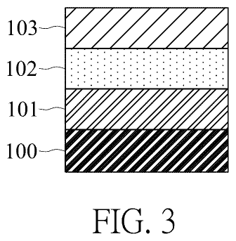

Reference is made to FIGS. 2 and 3, in which FIG. 2 is a top view of the gate all-around field effect transistor in process S10 according to the first embodiment of the present disclosure, and FIG. 3 is a cross-sectional view of the gate all-around field effect transistor in process S10 according to the first embodiment of the present disclosure.

FIG. 3 is a cross-sectional view taken along a section line CS1, and in the remaining cross-sectional views, unless otherwise specified, they are also taken along the section line CS1 and are not shown separately.

In process S10, a first sacrificial layer 101, a channel layer 102 and a protective layer 103 are formed on a substrate 100. The substrate 100 may include silicon, germanium, glass or other materials. The first sacrificial layer 101 may include one or more of titanium nitride, titanium, tungsten, silicon nitride and silicon dioxide. The first sacrificial layer 101 may be deposited to a thickness in a range of 1 nm to 1 μm by atomic layer deposition (ALD), sputtering, plasma enhanced chemical vapor deposition (PECVD), or epitaxy techniques. The channel layer 102 may be made of amorphous indium gallium zinc oxide (IGZO), II-VI materials, III-V materials, IV materials or two-dimensional materials. The channel layer 102 may be deposited to a thickness in a range of 1 nm to 1000 nm by atomic layer deposition (ALD) or sputtering.

For example, after a thermal oxide layer is deposited on a surface of a silicon wafer substrate, a silicon nitride layer (that is the first sacrificial layer 101) may be deposited to a thickness of 200 nm at 300° C. by plasma-enhanced chemical vapor deposition (PECVD). Subsequently, In₂O₃ and IGZO target materials may be deposited to form the channel layer 102, by co-sputtering, for example, with an atomic composition ratio of In:Ga:Zn:O=1:1:1:4 mol %.

It should be emphasized that, the protective layer 103 includes one or more of titanium nitride, titanium, tungsten, silicon nitride and silicon dioxide, which are different from materials of the channel layer 102. The protective layer 103 may have a thickness in a range of 1 nm to 1000 nm. The protective layer 103 may prevent the channel layer 102 from being adversely affected in a photoresist stripping process and may be serve as an etching stop layer. In addition, in consideration of subsequent processes, any material that is removable by SF₆ gas may be used as the protective layer 103.

In process S11, a first patterning process is performed on the first sacrificial layer, the channel layer and the protective layer to form a fin structure.

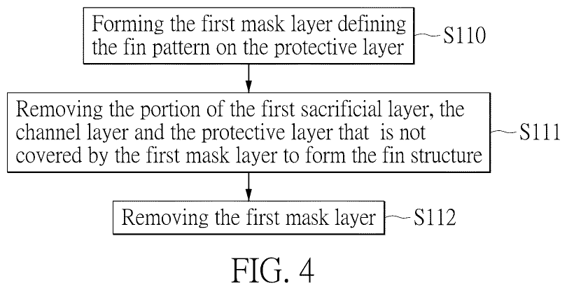

Reference is made to FIG. 4, which is a detailed flowchart diagram of process S11. The first patterning process of S11 described above may include procedures S110 to S112 shown in FIG. 4.

In procedure S110, a first mask layer defining the fin pattern is formed on the protective layer.

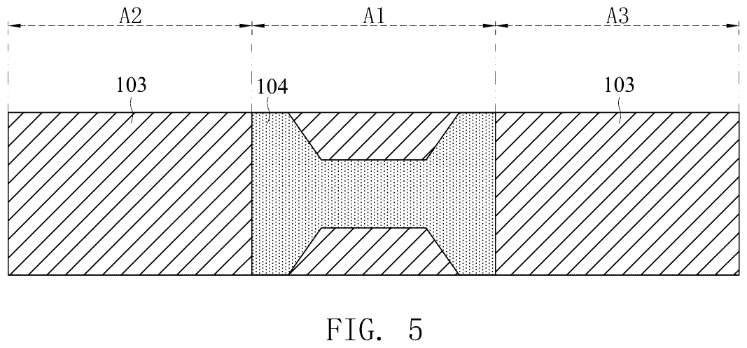

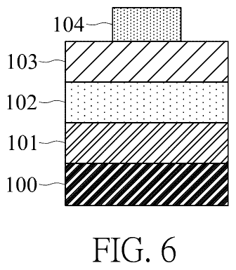

Reference is made to FIGS. 5 and to 6, in which FIG. 5 is a top view of the gate all-around field effect transistor in procedure S110 according to the first embodiment of the present disclosure, and FIG. 6 is a cross-sectional view of the gate all-around field effect transistor in procedure S110 according to the first embodiment of the present disclosure.

For example, the first mask layer 104 may be a photoresist layer (formed of a photoresist material or Si₃N₄), and may be patterned with a fin pattern by electron beam (e-beam) lithography. In the top view, the substrate 100 may define a channel region A1, and define a drain region A2 and a source region A3 that are located on two sides of the channel region A1. For example, the fin pattern may be defined in the channel region A1 in a funnel-like shape.

In procedure S111, a portion of the first sacrificial layer, the channel layer and the protective layer that is not covered by the first mask layer is removed to form the fin structure.

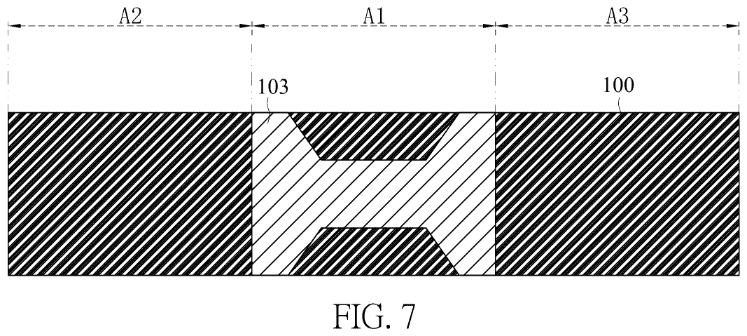

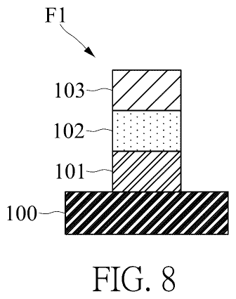

Reference is made to FIGS. 7 to 8, in which FIG. 7 is a top view of the gate all-around field effect transistor in procedure S111 according to the first embodiment of the present disclosure, and FIG. 8 is a cross-sectional view of the gate all-around field effect transistor in procedure S111 according to the first embodiment of the present disclosure.

In procedure S111 of FIG. 4, a fin structure F1 may be formed by reactive ion etching (RIE) as shown in FIGS. 7 and 8.

In procedure S112 of FIG. 4, the first mask layer 104 is removed, for example, by wet etching or dry etching. The wet etching process may involve the use of buffered oxide etchant (BOE) or hot phosphoric acid (H₃PO₄). The dry etching process may utilize reactive ion etching (RIE) or inductively coupled plasma reactive ion etching (ICP-RIE) process.

It is emphasized that the protective layer 103 plays an important role in performance of the gate all-around field effect transistor. If the protective layer 103 is not used, oxygen doping concentration in the channel layer 10 is increased in the photoresist stripping process, which results in an increase in the amount of weakly bonded oxygen. In oxide semiconductors such as IGZO (In—Ga—Zn—O), if oxygen atoms are weakly bonded to metal elements in material, negatively charged centers may form locally. These negatively charged centers exert Coulomb forces on free carriers, increasing electron scattering, thereby reducing carrier mobility, which ultimately results in increased series resistance and decreased on-current. By disposing the protective layer 103, the channel layer 102 is prevented from doping with excessive oxygen during removal of the first mask layer 104. In addition, the protective layer 103 may serve as an etching stop layer during the removal of the first mask layer 104.

As shown in FIG. 1, in process S12, a composite field oxide layer is formed to cover the fin structure and the substrate and disposed to surround the fin structure F1.

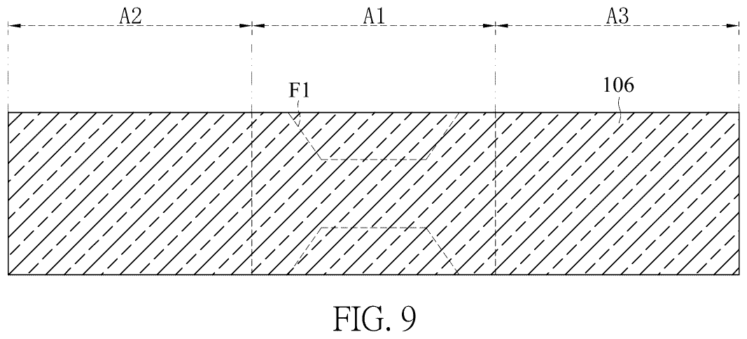

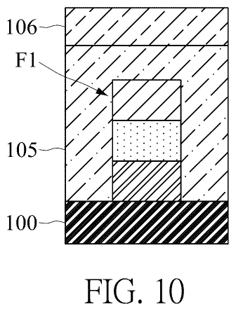

Reference is made to FIGS. 9 and 10, in which FIG. 9 is a top view of the gate all-around field effect transistor in process S12 according to the first embodiment of the present disclosure, and FIG. 10 is a cross-sectional view of the gate all-around field effect transistor in process S12 according to the first embodiment of the present disclosure.

In process S12 of FIG. 1, the composite field oxide layer includes a second sacrificial layer 105 (such as silicon nitride (SiN)) and a field oxide layer 106 (such as silicon dioxide (SiO₂)) that are sequentially stacked on the substrate 100 and the fin structure F1 as shown in FIGS. 9 and 10. A thickness of the second sacrificial layer 105 and a thickness of the field oxide layer 106 are in a range from 1 nm to 1000 nm. The composite field oxide layer may be deposited by PECVD, thermal oxidation or ALD.

In process S13 of FIG. 1, a second patterning process is performed on the composite field oxide layer to remove a portion of the composite field oxide layer in the channel region, and another portion of the composite field oxide layer in the drain region and the source region on two sides of the channel regions is retained.

The second patterning process is primarily used to retain the composite field oxide layer in the drain and source regions on the two sides of the channel region, and only the field oxide layer 106 in the channel region is removed.

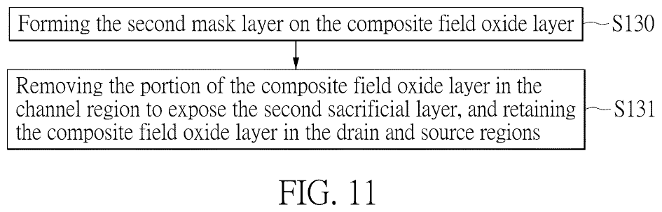

Reference is made to FIGS. 1 and 11, which is a detailed flowchart diagram of process S13. The second patterning process of S13 shown in FIG. 1 may include procedures S130 and S131 shown in FIG. 11.

In procedure S130, a second mask layer 107 is formed on the composite field oxide layer. The second mask layer 107 defines the channel region A1, the drain region A2 and the source region A3 that correspond to the fin structure F1.

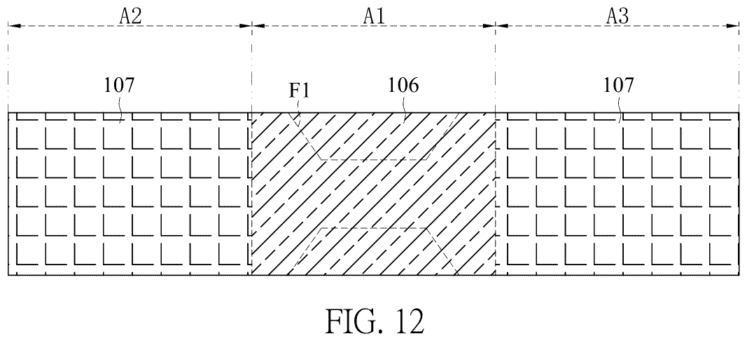

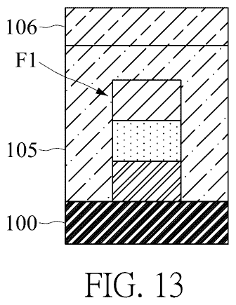

Reference is made to FIGS. 12 and 13, in which FIG. 12 is a top view of the gate all-around field effect transistor in procedure S130 according to the first embodiment of the present disclosure, and FIG. 13 is a cross-sectional view of the gate all-around field effect transistor in procedure S130 according to the first embodiment of the present disclosure.

As shown in FIGS. 12 and 13, patterns formed by the second mask layer 107 only covers the drain region A2 and the source region A3, but does not cover the channel region A1.

In procedure S131 of FIG. 11, one portion of the composite field oxide layer in the channel region is removed to expose the second sacrificial layer, and another portion of the composite field oxide layer in the drain region and the source region is retained.

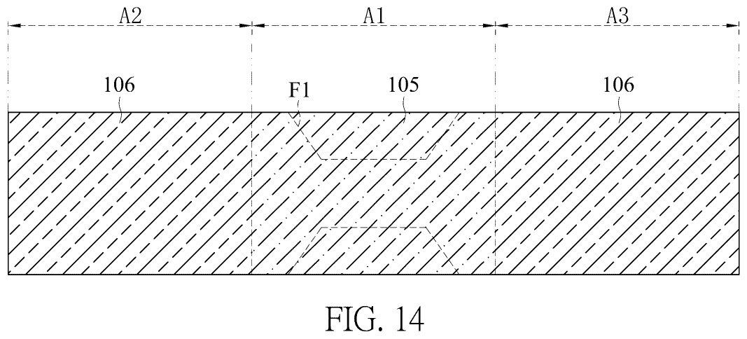

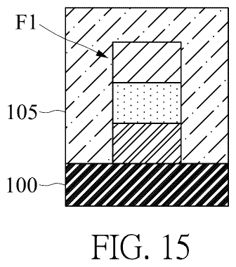

Reference is made to FIGS. 14 to 15, in which FIG. 14 is a top view of the gate all-around field effect transistor in procedure S131 according to the first embodiment of the present disclosure, and FIG. 15 is a cross-sectional view of the gate all-around field effect transistor in procedure S131 according to the first embodiment of the present disclosure.

In procedure S131 of FIG. 11, a buffered oxide etchant (BOE) may be used. Since an etching rate of SiN (included in the second sacrificial layer 105) is lower than that of SiOₓ (included in the field oxide layer 106), BOE etching is stopped at the SiN as shown in FIG. 15. If the field oxide layer 106 is not included in the gate stack layer, sidewall residues may be generated during subsequent etching processes of the gate stack layer, which may result in severe gate leakage.

In process S14 of FIG. 1, the composite field oxide layer, the protective layer and the first sacrificial layer in the channel region are removed to release the channel layer.

In process S14 of FIG. 1, the composite field oxide layer, the protective layer 103 and the first sacrificial layer 101 in the channel region A1 as shown in FIGS. 7 and 8 are removed by selective etching. As a result, a channel portion of the channel layer 102 in the channel region A1 is suspended above the substrate 100, and is, for example, spaced apart from the substrate 100 by a predetermined distance, to form a wraparound gate structure.

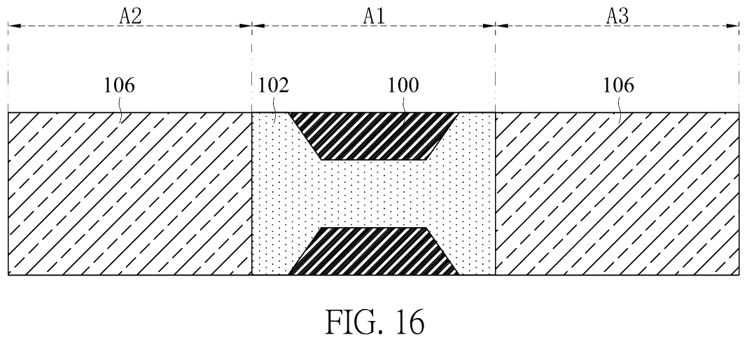

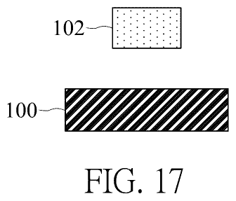

Reference is made to FIGS. 16 and 17, in which FIG. 16 is a top view of the gate all-around field effect transistor in process S14 according to the first embodiment of the present disclosure, and FIG. 17 is a cross-sectional view of the gate all-around field effect transistor in process S14 according to the first embodiment of the present disclosure.

For example, the inductively coupled plasma reactive ion etching (ICP-RIE) process using SF₆ gas may be employed to release the channel layer 102. Fluorine radicals react with SiN and SiOₓ to form gaseous by-products, whereas fluorides of a-IGZO remain in a solid state, thereby enabling a high selective etching. SiN is chosen as the material for the sacrificial layer due to its relatively high etching rate.

In addition, the composite field oxide layer in the drain region A2 and the source region A3 is retained due to a slow etching rate of SiOₓ in RIE, and the channel layer 102 (such as a-IGZO) is not affected by etching. In addition, due to bonding characteristics of the a-IGZO material, for example, bonding energy of indium oxygen (In—O) bond is low and/or local bonding energy of some oxygen bonds is weak, oxygen atoms are more easily separated, thereby forming a large number of oxygen vacancies in the channel layer 102. Preferably, the SF6 gas may be used for a longer period of time in the etching process so that fluorine atoms can passivate the channel layer 102 and fill the oxygen vacancies therein, thereby improving electrical control of the channel layer 102 and reducing the series resistance of the gate all-around field effect transistor.

In process S15 of FIG. 1, an oxygen assisted annealing process is performed on the released channel layer.

Similarly, as described above, due to the bonding characteristics of the a-IGZO material, a large number of oxygen vacancies are easily formed in the channel layer 102. In oxygen-assisted annealing, for example, at a low temperature (in a range of 200° C. to 400° C.) or a high temperature (in a range of 450° C. to 600° C.), predetermined annealing time and an oxygen flow rate are controlled such that oxygen molecules react with the oxygen vacancies on a surface of the-IGZO material and oxygen atoms are self-aligned. As a result, the oxygen vacancies are reduced, thereby improving the electrical control of the channel layer 102 and reducing the series resistance of the gate all-around field effect transistor.

In process S16 of FIG. 1, a gate stack layer is formed on the composite field oxide layer in the drain region and the source region, on the substrate in the channel region, and on a surface of the channel layer.

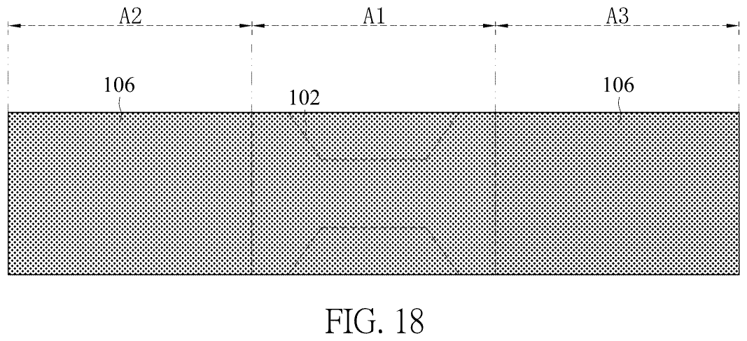

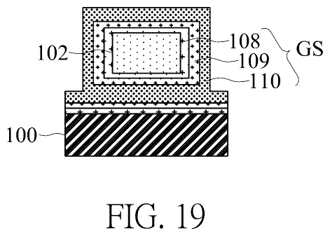

Reference is made to FIGS. 18 to 19, in which FIG. 18 is a top view of the gate all-around field effect transistor in process S16 according to the first embodiment of the present disclosure, and FIG. 19 is a cross-sectional view of the gate all-around field effect transistor in process S16 according to the first embodiment of the present disclosure.

In process S16 of FIG. 1, a gate insulating layer 108, a first gate metal layer 109 and a second gate metal layer 110 may be sequentially formed, together forming a gate stack layer GS on the composite field oxide layer, the substrate 100 in the channel region A1 and a surface of the channel layer 102 by ALD. The gate insulating layer 108 is disposed around the channel layer 102 and may include a high-k dielectric layer (such as Al₂O₃, HfO₂, TiO₂, or ZrO₂). The gate insulating layer 108 may be deposited to a thickness in the range of 1 nm to 1000 nm by ALD, thereby enhancing a channel control ability of a gate. The first gate metal layer 109 is disposed around the gate insulating layer 108, and may be made of titanium nitride and deposited to a thickness in the range of 1 nm to 1000 nm by ALD or PVD. Titanium nitride (TiN), tungsten, aluminum, titanium or other materials may be deposited to a thickness in the range of 1 nm to 1000 nm to form the gate metal layer 110 by ALD or PVD. The second gate metal layer 110 is disposed around the first gate metal layer 109.

In process S17 of FIG. 1, a third patterning process is performed on the gate stack layer to remove the gate stack layer in the drain region and the source region.

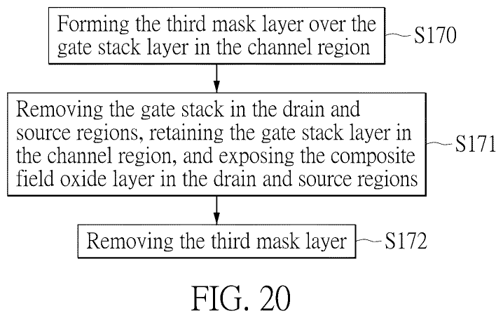

Reference is made to FIG. 20, which is a detailed flowchart diagram of process S17. The third patterning process of S17 shown in FIG. 1 includes procedures S170 to S172 shown in FIG. 20.

In procedure S170 of FIG. 20, a third mask layer is formed on the gate stack layer in the channel region.

In procedure S171, the gate stack layer in the drain region and the source region is removed, the gate stack layer in the channel region is retained, and the composite field oxide layer in the drain region and the source region is exposed.

In process S172, the third mask layer is removed.

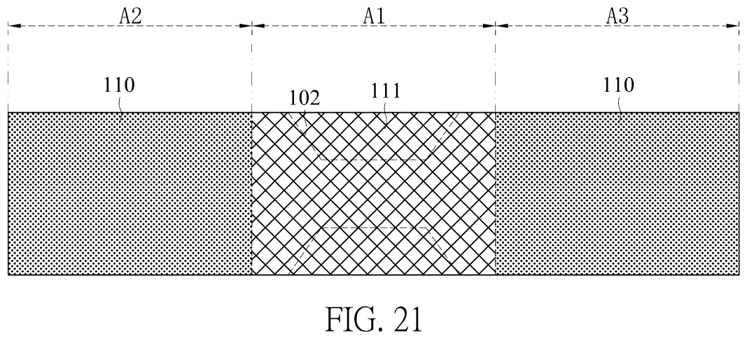

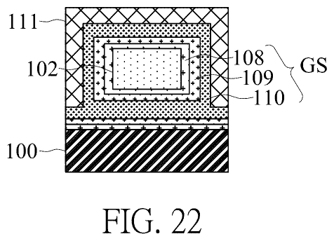

Reference is made to FIGS. 21 and 22, in which FIG. 21 is a top view of the gate all-around field effect transistor in procedure S170 according to the first embodiment of the present disclosure, and FIG. 22 is a cross-sectional view of the gate all-around field effect transistor in procedure S170 according to the first embodiment of the present disclosure.

In the procedure S170 of FIG. 20, as shown in FIGS. 21 and 22, a third mask layer 111 is formed on the gate stack layer GS in the channel region A1. Then, the gate stack layer GS in the drain region A2 and the source region A3 is removed, the gate stack layer in the channel region A1 is retained, and the composite field oxide layer in the drain region A2 and the source region A3 is exposed.

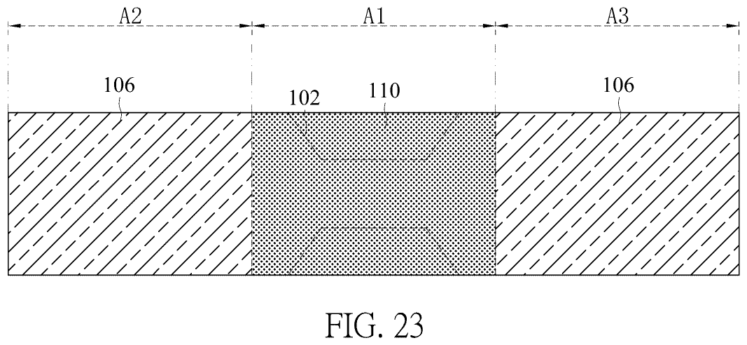

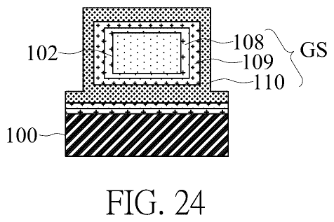

Reference is made to FIGS. 23 and 24, in which FIG. 23 is a top view of the gate all-around field effect transistor in process S172 according to the first embodiment of the present disclosure, and FIG. 24 is a cross-sectional view of the gate all-around field effect transistor in process S172 according to the first embodiment of the present disclosure.

In the above process S172 of FIG. 20, the third mask layer 111 is removed as shown in FIGS. 23 and 24.

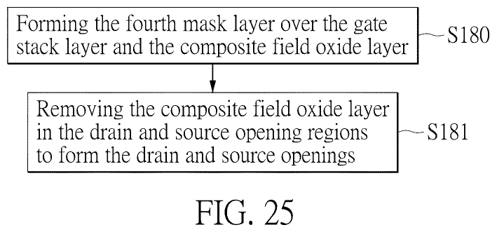

Reference is made to FIG. 25, which is a detailed flowchart diagram of process S18.

In process S18, a fourth patterning process is performed on the composite field oxide layer to form a drain opening in the drain region and a source opening in the source region.

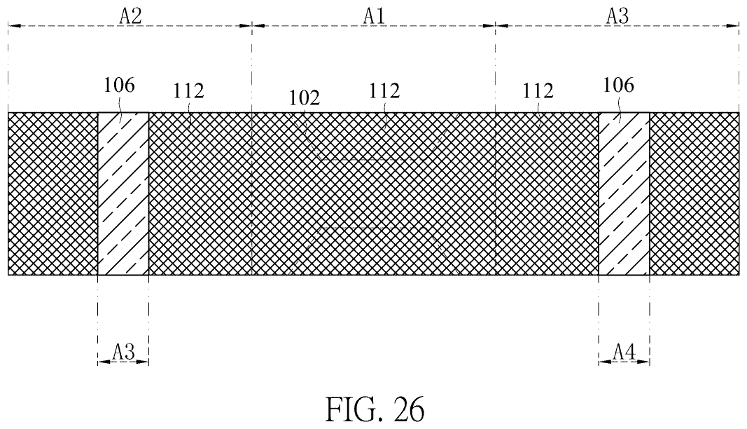

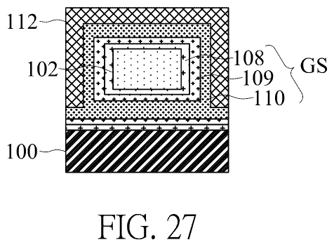

Reference is made to FIGS. 25 to 27, in which FIG. 26 is a top view of the gate all-around field effect transistor in procedure S180 according to the first embodiment of the present disclosure, and FIG. 27 is a cross-sectional view of the gate all-around field effect transistor in procedure S180 according to the first embodiment of the present disclosure.

The fourth patterning process S18 of FIG. 1 includes procedures S180 and S181 shown in FIG. 25.

In procedure S180 of FIG. 25, a fourth mask layer is formed on the gate stack layer and the composite field oxide layer.

As shown in FIGS. 26 and 27, the fourth mask layer 112 covers the entire channel region A1, but only covers portions of the drain region A2 and the source region A3, so as to define a drain opening region A4 in the drain region A2 and a source opening region A5 in the source region A3. For example, the fourth mask layer 112 may be a photoresist.

In procedure S181 of FIG. 25, the composite field oxide layer in the drain opening region and the source opening region is removed to form the drain opening and the source opening.

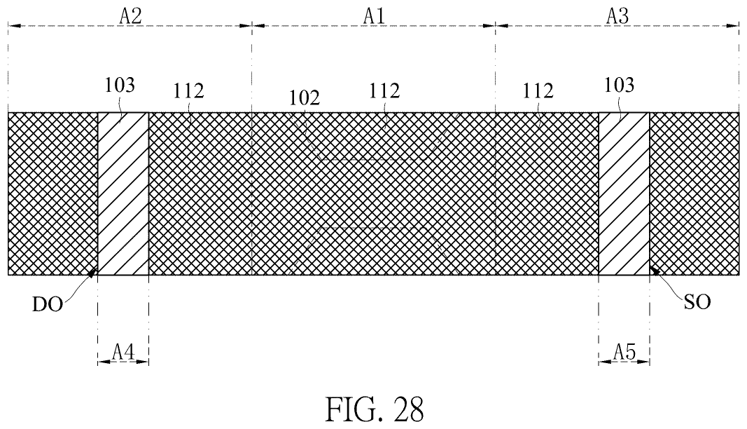

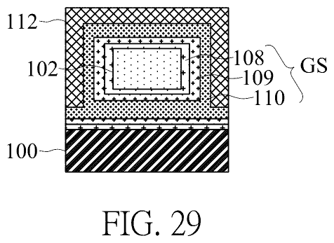

Reference is made to FIGS. 28 and 29, in which FIG. 28 is a top view of the gate all-around field effect transistor in procedure S181 according to the first embodiment of the present disclosure, and FIG. 29 is a cross-sectional view of the gate all-around field effect transistor in procedure S181 according to the first embodiment of the present disclosure.

The protective layer 103 is exposed by a drain opening DO and a source opening SO. The protective layer 103 also serves as an etching stop layer during the removal of the composite field oxide layer in the drain opening region A4 and the source opening region A5. Preferably, a width of the drain opening DO and a width of the source opening SO are in a range of 10 nm to 500 nm. In the absence of the protective layer 103, the width of the drain opening (DO) and the width of the source opening (SO) are typically limited to several nanometers to prevent damage to the thinner channel layer 102 during the etching process. This limitation constrains the size of the subsequently formed drain and source regions, resulting in an increased on-resistance of the gate-all-around field-effect transistor. Therefore, by disposing the protective layer 103 as the etching stop layer, the width of the drain opening DO and the width of the source opening SO are increased for reducing the series resistance of the gate all-around field effect transistor, and also preventing the channel layer 102 from being damaged during the etching process, thereby improving process yield.

In process S19 of FIG. 1, a drain electrode and a source electrode are respectively formed in the drain opening and the source opening, and are electrically connected to the protective layer.

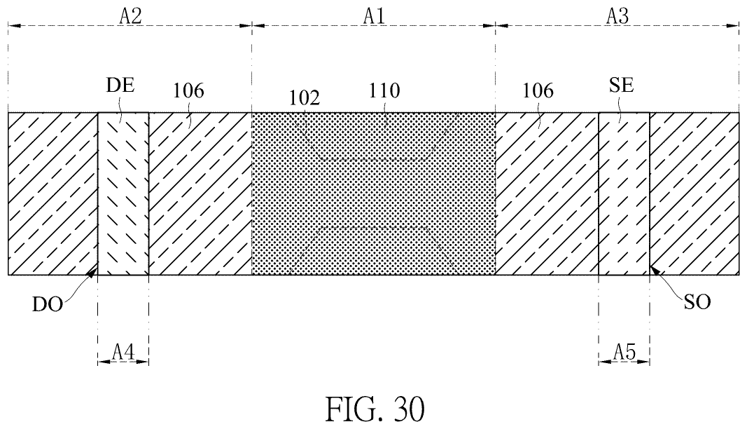

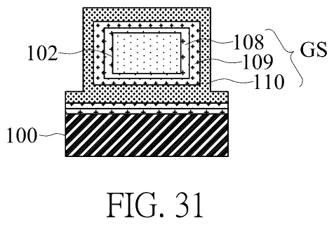

Reference is made to FIGS. 30 and 31, in which FIG. 30 is a top view of the gate all-around field effect transistor in process S19 according to the first embodiment of the present disclosure, and FIG. 31 is a cross-sectional view of the gate all-around field effect transistor in process S19 according to the first embodiment of the present disclosure.

In process S19 of FIG. 1, the source and drain metal layers may include TiN, Al, Ti, tungsten (W), indium tin oxide (ITO) or indium oxide (InO), and may be deposited to a thickness in the range of 1 nm to 1000 nm by ALD or sputtering, thereby ensuring good ohmic contact characteristics between the protective layer 103 and a drain electrode DE and a source electrode SE.

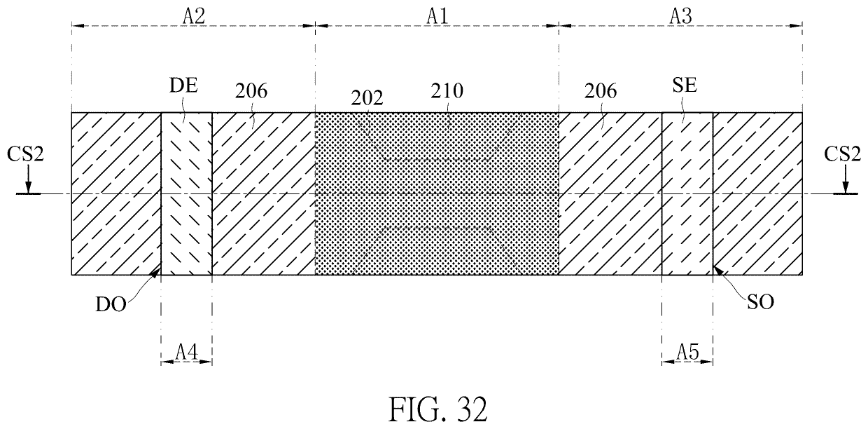

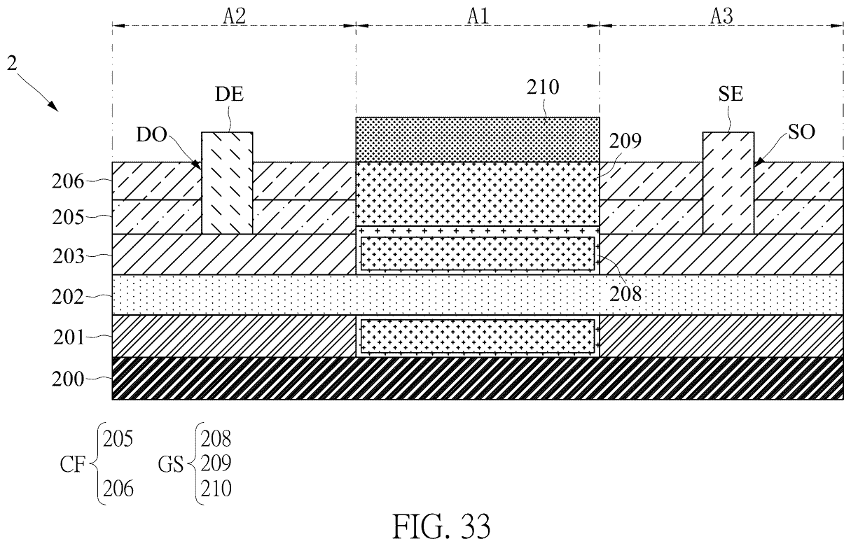

Reference is made to FIGS. 32 and 33, in which FIG. 32 is a top view of a gate all-around field effect transistor according to a second embodiment of the present disclosure, and FIG. 33 is a cross-sectional view of the gate all-around field effect transistor according to the second embodiment of the present disclosure. FIG. 33 is a cross-sectional view taken along a section line CS2.

The present disclosure provides a gate all-around field effect transistor 2, which includes a substrate 200, a first sacrificial layer 201, a channel layer 202, a protective layer 203, a composite field oxide layer CF, the drain electrode DE, the source electrode SE and the gate stack layer GS.

The substrate 200 defines the channel region A1, and defines the drain region A2 and the source region A3 on two sides of the channel region A1. The first sacrificial layer 201 is disposed on the substrate 200 in the drain region A2 and the source region A3.

The channel layer 202 is disposed on the first sacrificial layer 201 and extends from the drain region A2 to the source region A3. The channel layer 202 includes a channel portion that is disposed in the channel region A1 and spaced apart from the substrate 200 by a predetermined distance. As described in the above embodiments, the channel portion may be treated by self-aligned fluorine doping, oxygen assisted annealing or other processes. Specifically, time required for using SF6 gas may be extended in the etching process of the release channel layer 202 such that fluorine atoms can passivate the channel layer 202 and fill oxygen vacancies therein. Subsequently, the oxygen assisted annealing process may be performed on the released channel layer 202 such that oxygen molecules react with the oxygen vacancies on the surface of the a-IGZO material, thereby improving the electrical control of the channel layer 202 and reducing the series resistance of the gate all-around field effect transistor 2.

In addition, the protective layer 203 is disposed on the channel layer 202 in the drain region A2 and the source region A3. By disposing the protective layer 203, it can serve as the etching stop layer during processes, the process yield of the gate all-around field effect transistor 2 is improved, and constraints on the widths of the drain opening DO and the source opening SO are reduced. Therefore, good ohmic contact characteristics can be established between the protective layer 103 and the drain electrode DE and the source electrode SE. As a result, the series resistance of the gate all-around field effect transistor 2 is reduced and the on-current of the gate all-around field effect transistor 2 is increased.

On the other hand, the composite field oxide layer CF is disposed on the protective layer and is located in the drain region A2 and the source region A3. The composite field oxide layer CF includes a second sacrificial layer 205 and a field oxide layer 206 that are stacked in sequence, and has a drain opening DO in the drain region A2 and a source opening SO in the source region A3. The protective layer 203 is exposed by the drain opening DO and the source opening SO. The drain electrode DE is disposed in the drain opening DO and the source electrode SE is disposed in the drain opening DO. The drain electrode DE and the source opening SO are in electrical contact with the protective layer 203.

The gate stack layer GS serves as the gate of the gate all-around field effect transistor 2 and is disposed on the substrate 200 in the channel region A1, and the gate stack layer GS is disposed around the channel layer 202 to form a gate-all-around (GAA) structure. In this configuration, the on-current is increased, gate control capability is improved, and subthreshold swing (SS) and an off current are reduced. Similar to the above embodiments, the gate stack layer GS may include a gate insulating layer 208, a first gate metal layer 209 and a second gate metal layer 210.

It should be understood that, the gate all-around field effect transistor 2 only includes the single channel layer 202 as exemplified in the second embodiment, but in practice, may include the plurality of single channel layers 202.

In detail, the all-around field effect transistor 2 includes the plurality of channel layers 202 that are stacked and disposed around all the channel layers 202 for improving control capability of each channel layer 202. In addition, a sacrificial layer and a gap filling layer (that is a spacer layer) may be disposed between two adjacent ones of the plurality of channel layers 202. Gap filling material such as Al2O3, SiN, SiO2 may be used for supporting the channel layers 202 and controlling parasitic effects. In addition, the drain electrode DE and the source electrode SE also need to be in electrical contact with each channel layer 202.

### Beneficial Effects of the Embodiments

One beneficial effect of the present disclosure is that, the present disclosure provides the gate-all-around field-effect transistor and the method of fabricating the same, which exhibits low subthreshold swing (SS), low off-state current, good scaling ability, a high on/off current ratio, and a positive gate threshold voltage.

Another beneficial effect of the present disclosure is that, the gate-all-around field-effect transistor has good saturation characteristics under a high drain voltage, the reduced series resistance, the increased on-current, and the high yield in manufacturing. Therefore, the gate-all-around field-effect transistor and the method of fabricating the same are suitable for large-scale mass production.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for fabricating a gate all-around field effect transistor, comprising:
sequentially forming a first sacrificial layer, a channel layer and a protective layer on a substrate;
performing a first patterning process on the first sacrificial layer, the channel layer and the protective layer to form a fin structure;
forming a composite field oxide layer to cover the fin structure and the substrate and to surround the fin structure;
performing a second patterning process on the composite field oxide layer to remove one portion of the composite field oxide layer in a channel region and retain another portion of the composite field oxide layer in a drain region and a source region on two sides of the channel region;
removing the protective layer, the first sacrificial layer and the one portion of the composite field oxide layer in the channel region to release the channel layer;
forming a gate stack layer on the another portion of the composite field oxide layer in the drain region and the source region, the substrate in the channel region and a surface of the channel layer;
performing a third patterning process on the gate stack layer to remove the gate stack layer from the drain region and the source region;
performing a fourth patterning process on the composite field oxide layer to form a drain opening in the drain region and a source opening in the source region; and
forming a drain electrode in the drain opening and a source electrode in the source opening and electrically connecting the drain electrode and the source electrode to the protective layer.

2. The method for fabricating the gate all-around field effect transistor according to claim 1, further comprising:
performing an oxygen assisted annealing process on the channel layer that is released, and performing an inductively coupled plasma reactive ion etching process to remove the protective layer, the first sacrificial layer and the portion of the composite field oxide layer in the channel region;
wherein the inductively coupled plasma reactive ion etching process includes a process of: performing self-aligned fluorine doping on the channel layer by using SF6 gas.

3. The method for fabricating the gate all-around field effect transistor according to claim 1, wherein the first patterning process includes procedures:
forming a first mask layer defining a fin pattern on the protective layer;
removing a portion of the first sacrificial layer, the channel layer and the protective layer that is not covered by the first mask layer to form the fin structure; and
removing the first mask layer, during which the protective layer serves as an etching stop layer.

4. The method for fabricating the gate all-around field effect transistor according to claim 1, wherein the second patterning process includes procedures of:
forming, on the composite field oxide layer, a second mask layer defining the channel region, the drain region and the source region that correspond to the fin structure; and
removing the portion of the composite field oxide layer in the channel region to expose a second sacrificial layer of the composite field oxide layer and retain the composite field oxide layer in the drain region and the source region.

5. The method for fabricating the gate all-around field effect transistor according to claim 1, wherein the channel layer includes a channel portion that is disposed in the channel region and spaced apart from the substrate by a predetermined distance.

6. The method for fabricating the gate all-around field effect transistor according to claim 1, wherein the third patterning process includes procedures of:
forming a third mask layer on the gate stack layer in the channel region;
removing the gate stack in the drain region and the source region to expose the composite field oxide layer in the drain region and the source region and retain the gate stack layer in the channel region; and
removing the third mask layer.

7. The method for fabricating the gate all-around field effect transistor according to claim 1, wherein the fourth patterning process includes:
forming a fourth mask layer on the gate stack layer and the composite field oxide layer to define a drain opening region in the drain region and a source opening region in the source region;
using the protective layer as an etching stop layer and removing the composite field oxide layer in the drain opening region and the source opening region to form the drain opening and the source opening for exposing the protective layer.

8. The method for fabricating the gate all-around field effect transistor according to claim 1, wherein a width of the drain opening and a width of a source opening are in a range of 10 nm to 500 nm, the protective layer has a thickness in a range of 1 nm to 1000 nm, and the protective layer includes one or more of titanium nitride, titanium, tungsten, silicon nitride and silicon dioxide that are different from materials of the channel layer.

9. The method for fabricating the gate all-around field effect transistor according to claim 1, wherein the composite field oxide layer includes a second sacrificial layer and a field oxide layer that are sequentially stacked, the second sacrificial layer includes one or more of titanium nitride, titanium, tungsten, silicon nitride and silicon oxide, and the field oxide layer includes one or more of titanium nitride, titanium, tungsten, silicon nitride and silicon dioxide.

10. The method for fabricating the gate all-around field effect transistor according to claim 1, wherein the channel layer includes one or more of amorphous indium gallium zinc oxide, a II-VI group material, III-V group materials, IV group materials and two-dimensional materials.

11. A gate all-around field effect transistor, comprising:
a substrate, wherein the substrate defines a channel region, and defines a drain region and a source region on two sides of the channel region;
a first sacrificial layer disposed on the substrate in the drain region and the source region;
a channel layer disposed on the first sacrificial layer and extending from the drain region to the source region;
a protective layer disposed on the channel layer in the drain region and the source region;
a composite field oxide layer disposed on the protective layer in the drain region and the source region, wherein the composite field oxide layer has a drain opening in the drain region and a source opening in the source region, and the drain opening and the source opening expose the protective layer;
a drain electrode and a source electrode that are in electrical contact with the protective layer, wherein the drain electrode is disposed in the drain opening and the source electrode is disposed in the source opening; and
a gate stack layer disposed on the substrate in the channel region and disposed to surround the channel layer.

12. The gate all-around field effect transistor according to claim 11, wherein the gate stack layer includes:
a gate insulating layer disposed around the channel layer;
a first gate metal layer disposed around the gate insulating layer; and
a second gate metal layer disposed around the first gate metal layer.

13. The gate all-around field effect transistor according to claim 11, wherein the channel layer has a channel portion that is disposed in the channel region and spaced apart from the substrate by a predetermined distance.

14. The gate all-around field effect transistor according to claim 13, wherein the channel portion of the channel layer is treated by self-aligned fluorine doping and oxygen assisted annealing.

15. The gate all-around field effect transistor according to claim 11, wherein a width of both the drain opening and a width of the source opening are in a range of 10 nm to 500 nm.

16. The gate all-around field effect transistor according to claim 11, wherein the protective layer has a thickness in a range of 1 nm to 1000 nm.

17. The gate all-around field effect transistor according to claim 11, wherein the protective layer includes one or more of titanium nitride, titanium, tungsten, silicon nitride and silicon dioxide, which are different from materials of the channel layer.

18. The gate all-around field effect transistor according to claim 11, wherein the composite field oxide layer includes a second sacrificial layer and a field oxide layer that are sequentially stacked.

19. The gate all-around field effect transistor according to claim 18, wherein the second sacrificial layer includes one or more of titanium nitride, titanium, tungsten, silicon nitride and silicon oxide, and the field oxide layer includes one or more of titanium nitride, titanium, tungsten, silicon nitride and silicon dioxide.

20. The gate all-around field effect transistor according to claim 11, wherein the channel layer includes one or more of amorphous indium gallium zinc oxide, II-VI group materials, III-V group materials, IV group materials and two-dimensional materials.
